(19) United States
(12) Patent Application Publication
(10) Pub. No.: US 2011/0204382 A1
(43) Pub. Date: Aug. 25, 2011

(54) LAYERED STRUCTURES COMPRISING SILICON CARBIDE LAYERS, A PROCESS FOR THEIR MANUFACTURE AND THEIR USE

(75) Inventors: Alexander Traut, Huerth (DE); Norbert Wagner, Mutterstadt (DE); Chien Hsueh Steve Shih, Taipei (TW)

(73) Assignee: BASE SE, Ludwigshafen (DE)

(21) Appl. No.: 12/989,661

(22) PCT Filed: Apr. 27, 2009
(86) PCT No.: PCT/EP2009/055064

§ 371 Date: Oct. 26, 2010

(30) Foreign Application Priority Data
May 8, 2008 (EP) 08103863.0

(51) Int. Cl. H01L 29/24; H01L 21/04

(52) U.S. Cl. 257/77; 438/778; 257/E29.104; 257/E21.054

(57) ABSTRACT

A layered structure comprising in this order: (A) a silicon carbide layer, (B) at least one stratum (b1) located at least one major surface of the silicon carbide layer (A), (b2) chemically bonded to the bulk of the silicon carbide layer (A) by silicon-oxygen and/or silicon-carbon bonds, (b3) covering the at least one major surface of the silicon carbide layer (A) partially or completely, and (b4) having a higher polarity than a pure silicon carbide surface as exemplified by a contact angle with water which is lower than the contact angle of water with a pure silicon carbide surface; and (C) at least one dielectric layer, which covers the stratum or the strata (B) partially or completely and is selected from inorganic and inorganic-organic hybrid dielectric layers; a process for its manufacture and its use.

### FIELD OF THE INVENTION

The present invention is directed to novel layered structures comprising silicon carbide layers.

Moreover, the present invention is directed to a novel process for preparing layered structures comprising silicon carbide layers.

Additionally, the present invention is directed to the use of the novel layered structures comprising silicon carbide layers and of the layered structures comprising silicon carbide layers manufactured by way of the novel process

### BACKGROUND OF THE INVENTION

Due to its numerous theoretical and practical advantages, silicon carbide is extensively used in electronic devices. These advantages include a wide band gap, a high breakdown field, a high thermal conductivity, a high electron drift velocity, an excellent thermal stability, an excellent radiation resistance or “hardness”, an excellent hardness and a high chemical stability. Therefore, silicon carbide has significant advantages with respect to high power operation, high-temperature operation, radiation hardness, and absorption and emission of high-energy photons in the blue, violet, and ultraviolet regions of the spectrum. Due to its high chemical stability, it also exhibits significant advantages as a protective layer material, in particular, an etch stop layer material in the manufacture of semiconductor microdevices or integrated circuits (ICs).

The power and usefulness of today's digital integrated circuit devices is largely attributed to the increasing levels of integration. More and more components (resistors, diodes, transistors, and the like) are continually being integrated into the underlying chip or integrated circuit (IC). The starting material for typical ICs is high purity silicon.

The geometry of the features of the IC components are commonly defined by photolithography. Very fine surface geometry can be accurately reproduced by this technique. The photolithography process is used to define component regions and build up components one layer on top of another. Complex ICs can often have many different built-up layers, each layer having components, each layer having differing interconnections and each layer stacked on top of the previous layer. The resulting topography of such complex ICs often resembles familiar terrestrial “mountain ranges”, with many “hills” and “valleys” as the IC components are built up on the underlying surface of the silicon wafer.

Submicron devices, e.g. transistors smaller than 1 μm in size, are formed in the various layers that form the IC. Thousands or millions of the submicron devices can be utilized in a typical IC. However, circuits are continually becoming more complex and more capable. Hence, there is a constant need for increasing the number of components that are included on an IC. However, the size of an IC is frequently limited to a given die size on a wafer. Consequently, a constant need arises to reduce the size of the devices in an IC.

As device size shrinks, the electrical Resistance-Capacitance (RC) delays and crosstalk associated with backend metallization become more significant. At some point, a threshold between the size of the device and the amount of interference it can sustain, is crossed. After this threshold, the operation of the device is compromised. Hence, a need arises to reduce the RC sensitivity of the deep submicron device.

One conventional method that reduces RC sensitivity of a device and an IC uses low dielectric constant materials (low-k materials) for deep submicron devices. However, low-k materials exhibit only poor adhesion to underlying silicon carbide layers utilized as protective layers and copper barrier layers in the ICs or etch stop layers in the manufacture of the ICs.

Various methods for ameliorating this problem have been proposed in the prior art.

Thus, the American U.S. Pat. No. 6,424,038 B1 teaches a microelectronic conductor structure comprising a substrate, a silicon carbide layer formed over the substrate, a silicon nitride layer formed upon the silicon carbide layer, a patterned low dielectric constant dielectric layer formed upon the silicon nitride layer, and a patterned conductor layer formed interposed between the patterns of the patterned low dielectric constant dielectric layer. In this structure, the laminate consisting of the silicon carbide layer and the silicon nitride layer functions as the etch stop layer, the silicon nitride layer improving the interface adhesion between the etch stop layer and the low-k material layer. In a comparative experiment it is demonstrated that an aminosilane adhesion promoter layer of a thickness of 20 nm cannot compensate for the absence of the silicon nitride layer. This means that the microelectronic devices fabricated with etch stop layers formed from silicon carbide laminated with silicon nitride provide a considerably lower leakage current than the microelectronic devices fabricated with etch stop layers formed of silicon carbide having laminated thereto the aminosilane adhesion promoter.

However, the manufacturer of the laminated etch stop layers consisting of a layer of silicon carbide and a layer of silicon nitride requires the deposition of silicon nitride by Chemical Vapor Deposition (CVD) or Plasma Enhanced Vapor Deposition (PVD) techniques, which techniques lead to materials being very different from aminosilane adhesion promoter layers.

The American patent application US 2003/035904 A1 teaches the improvement of the adhesion between a silicon carbide etch stop layer and a low-k material layer by way of subjecting the top surface of the silicon carbide layer to an oxygen-containing plasma so that a hydrophilic surface exhibiting a contact angle with water of 5 to 10° is obtained. Thereafter, the hydrophilic surface is coated with an adhesion promoter having hydrophilic and hydrophobic groups. The hydrophilic groups orient themselves towards the hydrophilic surface of the silicon carbide layer. The adhesion promoter is baked to yield the adhesion promoter coating layer having a hydrophobic surface. This way, a very good adhesion to the subsequently applied organic polymeric low-k material layer is achieved.

However, this method is not suited for the improvement of the adhesion between a silicon carbide layer and an inorganic or an inorganic-organic hybrid low-k material layer.

The American patent application US 2003/017642 A1 teaches the use of a structure comprising multiple layers of differing organic concentrations (gradient-carbon layers), which layers can conceptually be thought of as a single graded layer wherein the carbon concentration gradually increases as the distance moves away from the substrate, e.g. a silicon carbide substrate. The graded layer functions as a low-k electric layer having a good adhesion to the substrate.

However, the process for fabricating the gradient layer is laborious. Moreover, the process is not suitable for improving the adhesion between the silicon carbide surface and a conventional low-k material layer on the basis of silicon dioxide or of inorganic-organic hybrid materials.

The American patent application US 2007/173054 A1 teaches a method of improving the adhesion between a silicon carbide layer and a low-k dielectric material layer by oxidizing the surface of the silicon carbide with a carbon dioxide containing plasma. Thereafter, the surface is made in contact with a hydrophilic chemical, as for example, an aqueous solution of dimethylacetamide and ammonium fluoride. This way the contact angle of the silicon carbide surface with water of 100° is lowered to 40° and the adhesion to low-k material layers of the basis of silicon dioxide is improved.

However, this method requires at least two process steps, in particular a plasma treatment and a treatment with an aqueous solution in a wet wafer washing chamber.

The American patent application US 2004/238967 A1 discloses an electronic structure comprising a metallic plate, a silicon carbide layer bonded to the metallic plate and an adhesion promoter layer bonded to the silicon carbide layer. The adhesion promoter layer is prepared by dipping the metal plate with the silicon carbide layer in a silane solution, followed by dripping off excess solution and drying for several minutes at a moderate temperature, as for example 15 to 20 min at 18 to 100° C. The adhesion promoter layer should have a thickness between 1 to 50 monolayers and may include silane coupling agents such as 3-glycidoxypropyltrimethoxysilane or -triethoxysilane or 3-(2-aminoethyl)propyltrimethoxysilane or -triethoxysilane. The electronic structure is embedded in a structural epoxy resin material as the adhesive material. The electronic structure is coupled to a semiconductor chip by way of the adhesive material. This way, a mechanism for dissipating heat from the semiconductor chip is provided.

However, the American patent application concerns a design which is completely different from the electronic devices here in question and remains silent as to whether such an adhesion promoter layer could improve the adhesion between a silicon carbide layer and a low-k material layer on the basis of silicon dioxide or of an inorganic-organic hybrid material and not only of an epoxy resin.

Other problems of silicon carbide/silicon dioxide interfaces such as interface trap density are ameliorated by incorporating nitrogen at the interface, as described in the American patent application US 2006/024978 A1.

Problems of passivating layers on silicon carbide surfaces associated with the presence of dopants and carbon-oxygen species are ameliorated by thermally-grown oxidation layers having a very low aluminium dopant concentration, as described in the American U.S. Pat. No. 5,629,531.

Therefore, the said American patent and patent applicant concern problems which are completely different from the adhesion problems of silicon carbide/inorganic or inorganic-organic hybrid low-k material interfaces. Consequently, they cannot provide the skilled artisan with hints and even less so with a technical teaching as to how to resolve the objects of the present invention.

### OBJECTS OF THE INVENTION

It was the object of the invention to provide a novel layered structure of comparatively simple design comprising a silicon carbide layer and at least one inorganic and/or inorganic-organic hybrid dielectric layer, in particular an inorganic and/or inorganic-organic hybrid dielectric layer having a lower dielectric constant k than silicon dioxide, the layered structure having an excellent adhesion between the silicon carbide layer and the inorganic and/or inorganic-organic hybrid dielectric layer. Additionally, the functions of the silicon carbide layer in the novel layered structure as copper diffusion barriers and protective layers in ICs and etch stop layers in the manufacture of ICs should not be impaired but significantly improved. Moreover, electrical Resistance-Capacitance (RC) delays and crosstalk associated with backend metallization should be avoided.

It was another object of the invention to provide a novel process for manufacturing layered structures of comparatively simple design comprising a silicon carbide layer and at least one inorganic and/or inorganic-organic hybrid dielectric layer, in particular one inorganic and/or inorganic-organic hybrid dielectric layer having a lower dielectric constant k than silicon dioxide. The novel process should be carried out with less steps than the prior art processes. Moreover, the novel process should have an excellent reproducibility and reliability and a very low failure rate. The obtained layered structures should exhibit an excellent interface adhesion. When used in ICs, they should significantly decrease electrical Resistance-Capacitance (RC) delays and crosstalk associated with backend metallization as compared with prior art layered structures. Additionally, in this application, the functions of the silicon carbide in the layered structures thus obtained as copper diffusion barriers and protective layers in ICs and etch stop layers in the manufacture of ICs should not be impaired but significantly improved.

### SUMMARY OF THE INVENTION

Accordingly, a novel layered structure has been found, the said novel layered structure comprising in this order:
(A) a silicon carbide layer,
(B) at least one stratum
   (b1) located at least one major surface of the silicon carbide layer (A),
   (b2) chemically bonded to the bulk of the silicon carbide layer (A) by silicon-oxygen and/or silicon-carbon bonds,
   (b3) covering the at least one major surface of the silicon carbide (A) layer partially or completely, and
   (b4) having a higher polarity than a pure silicon carbide surface as exemplified by a contact angle with water which is lower than the contact angle of water with a pure silicon carbide surface;
(C) at least one dielectric layer, which covers the stratum or the strata (B) partially or completely and is selected from inorganic and inorganic-organic hybrid dielectric layers.

Hereinafter, the novel layered structure will be referred to as “the structure of the invention”.

Moreover, a novel process for manufacturing a layered structure comprising in that order:
(A) a silicon carbide layer,
(B) at least one stratum
   (b1) located at least one major surface of the silicon carbide layer (A),
   (b2) chemically bonded to the bulk of the silicon carbide layer (A) by silicon-oxygen and/or silicon-carbon bonds,
   (b3) covering the at least one major surface of the silicon carbide layer (A) partially or completely, and
   (b4) having a higher polarity than a pure silicon carbide surface as exemplified by a contact angle with water which is lower than the contact angle of water with a pure silicon carbide surface; and
(C) at least one dielectric layer, which covers the stratum or the strata (B) partially or completely and is selected from inorganic and inorganic-organic hybrid dielectric layers,
   has been found, the said process comprising the steps of
(1) applying an organic solution of at least one silane selected from the group consisting of silanes of the general formula I:

RnSiX₄₋ₙ (I),

and silanes of the general formula II:

RₘX₃₋ₘSi—R—SiX₃₋ₘRₘ (II);

wherein the indices and the variables have the following meaning:
n 1 or 2;
m 0 or 1;
R organic moiety containing at least 2 carbon atoms, selected from the group consisting of moieties containing or consisting of substituted and unsubstituted, branched and linear, aliphatic, olefinically unsaturated and acetylenically unsaturated groups as well alicyclic and aromatic groups; and
X hydrolyzable atom or hydrolyzable moiety;
   on at least one major surface of the silicon carbide layer;
(2) drying the thus obtained layer consisting of the organic solution of the silane I and/or II by removing the volatile components;
(3) annealing the dried layer of the silane I at temperatures between 150 to 400° C. for 1 to 120 min to obtain the stratum (B); and
(4) applying at least one dielectric layer, which covers the stratum or the strata (B) partially or completely and is selected from inorganic and inorganic-organic hybrid dielectric layers;
   or, in the alternative,
(5) carrying out the process step (4) directly after the process step (1), and, thereafter, carrying out the process steps (2) and (3) during and/or after the process step (4).

Hereinafter, the novel process for manufacturing a layered structure is referred to as “the process of the invention”.

Last but not least, the novel use of the structures of the invention and the layered structures manufactured by the process of the invention in electronic devices has also been found. Hereinafter, this is referred to as “the use of the invention”.

### ADVANTAGES OF THE INVENTION

In view of the prior art discussed above, it was surprising and could not be expected by the skilled artisan that the objects of the invention could be solved by the structures, the process and the use of the invention.

In particular, it was surprising that the structures of the invention exhibited an excellent adhesion between the silicon carbide layer and the inorganic or inorganic-organic hybrid dielectric layer. Additionally, the functions of the silicon carbide layer in the structures of the invention as copper diffusion barriers and protective layers in ICs and etch stop layers in the manufacture of ICs were not be impaired but significantly improved. Moreover, electrical Resistance-Capacitance (RC) delays and crosstalk associated with backend metallization could be avoided so that improved submicron semiconductor devices could be designed.

Moreover, it was surprising that the process of the invention could be carried out with less steps than the prior art processes. Moreover, the process of the invention had an excellent reproducibility and reliability and a very low failure rate. The obtained layered structures, in particular the structures of the invention, exhibited an excellent interface adhesion. When used in ICs, they could significantly decrease electrical Resistance-Capacitance (RC) delays and crosstalk associated with backend metallization as compared with prior art layered structures. Additionally, in this application, the functions of the silicon carbide in the layered structures, in particular the structures of the invention thus obtained, as copper diffusion barriers and protective layers in ICs and etch stop layers in the manufacture of ICs were not impaired but significantly improved.

Due to their advantageous properties, the structures of the invention and the layered structures, in particular the structures of the invention, obtained by the process of the invention could be most advantageously used in various electronic devices.

### DETAILED DESCRIPTION OF THE INVENTION

The structure of the invention comprises a silicon carbide layer (A).

The silicon carbide layer (A) can be a silica carbide wafer or a silica carbide layer on top of a multitude of different materials and layers customarily used in electronic devices, in particular semiconductor devices. Examples for such materials and layers are silicon wafers, electrically conductive layers such as aluminum, copper, gold or silver layers, barrier layers such as titanium, titanium nitride, tantalum or tantalum nitride layers, and insulating layers such as silicon dioxide layers.

The thickness of the silicon carbide layer (A) depends on the intended use of the structure of the invention and, therefore, can vary broadly. Preferably, the silicon carbide layer (A) has a thickness between 5 nm and 1 μm, more preferably 10 and 500 nm and most preferably 10 to 200 nm.

The silicon carbide layer (A) can be manufactured by way of processes well-known in the art such as Chemical Vapor Deposition (CVD) or Plasma Enhanced Chemical Vapor Deposition (PECVD) as described, for example, in the American patent applications US 2004/147115 A1 or US 2006/110938 A1 or in the international patent application WO 2006/045920 A1 or sol-gel methods as described, for example, in the European patent application EP 0 482 782 A1.

The structure of the invention further comprises at least one, preferably one, stratum (B). The stratum (B) is located at least one major surface, preferably at one major surface, of the silicon carbide layer (A) and is chemically bonded to the bulk of the silicon carbide layer (A) by silicon oxygen and/or silicon-carbon bonds. In this way, the stratum (B) forms an integral part of the silicon carbide layer (A).

The stratum (B) covers the major surface of the silicon carbide layer (A) partially or completely, preferably completely.

It has a higher polarity than a pure silicon carbide surface as exemplified by a contact angle with water which is lower than the contact angle of water with a pure silicon carbide surface. Preferably, the contact angle with water is from 30 to 70°, more preferably from 35 to 60° and most preferably from 38 to 55°.

Preferably, the contact angle of the stratum (B) with water is equal to or greater than the contact angle of water with a pure silicon dioxide surface.

Preferably, the contact angle is measured by the dynamic sessile drop method as a function of time using a contact angle goniometer with a high-speed camera.

The stratum (B) can still exhibit an absorption in its IR spectrum in the wavenumber range of from 3000 to 2800 cm⁻¹. This means that the stratum (B) can still contain some moieties having aliphatic carbon-hydrogen bonds. However, the concentration of such moieties can also be so low as to be below the limit of detection.

The thickness of the stratum (B) can vary broadly. Preferably, the thickness is from 5 to 100 nm, more preferably 5 to 60 nm and most preferably 5 to 40 nm.

The structure of the invention further comprises at least one, preferably one, dielectric layer (C) covering the stratum or the strata (B) partially or completely. When it covers the stratum (B) partially, the dielectric layer (C) preferably forms a pattern corresponding to an electrical circuitry.

The dielectric layer (C) is selected from inorganic and inorganic-organic dielectric layers.

In principle, any inorganic or inorganic-organic hybrid dielectric material customarily used in electronic devices, in particular in semiconductor devices, can be used for the manufacture of the inorganic or the inorganic-organic hybrid dielectric layer (C). Preferably, the inorganic and the inorganic-organic hybrid dielectric layers (C) contain siloxane bonds. More preferably, the inorganic and the inorganic-organic hybrid dielectric layers (C) are having a dielectric constant k less than silicon dioxide. For purposes of briefness, such inorganic and inorganic-organic hybrid low-k dielectric layers (C) are hereinafter referred to as “low-k dielectric layers” or “low-k dielectric materials”.

Examples of advantageous low-k dielectric layers (C) are layers consisting of silicalites nanoparticles, which are microporous crystalline oxides of silicon that are pure-silicon analogs of zeolites, embedded in an amorphous glass as described in the American U.S. Pat. No. 6,827,982 B1, column 3, lines 45 to column 6; nanoporous silicon dioxide as described in the international patent application WO 01/78127 A2, page 11, second paragraph, or in the international patent application WO 01/86709 A2, page 8, line 25 to page 18, line 35; silicon oxide having a porosity of 10% or more as described in the international patent application WO 2004/027850 A1, page 10, line 1 to page 21, line 4; or the inorganic glasses and the inorganic-organic hybrid spin-on-glasses described in the American U.S. Pat. No. 6,424,038 B1, column 6, lines 40 to 67.

The thickness of the inorganic and the inorganic-organic hybrid dielectric layers (C) can vary broadly. Preferably, the thickness is in the range of from 10 to 500 nm, more preferably 10 to 250 nm and most preferably 10 to 100 nm.

Layered structures comprising silicon carbide layers (A), strata (B) and inorganic and/or inorganic-organic hybrid dielectric layers (C), in particular, the above described structures of the invention can be manufactured in various ways. Preferably, they are manufactured according to the process of the invention.

In the first step of the process of the invention, an organic solution of at least one silane, preferably of at least two silanes and, most preferably, of two silanes selected from the group consisting of silanes of the general formula I:

RₙSiX₄₋ₙ (I);

and silanes of the general formula II:

RₘX₃₋ₘSi—R—SiX₃₋ₘRₘ (II);

is applied to the surface of the silicon carbide layer (A).

In the general formula I the index n equals one or 2, preferably 1.

In the general formula I the index m equals 0 or 1, preferably 0.

In the general formulas I and II the variable R symbolizes an organic moiety containing at least 2 carbon atoms, selected from the group consisting of moieties containing or consisting of substituted and unsubstituted, branched and linear, aliphatic, olefinically unsaturated and acetylenically unsaturated groups as well alicyclic and aromatic groups.

The organic moieties R in the silanes of the general formula I containing two of these moieties and in the silanes of the general formula II can be the same or different from each other.

Thus, the organic moiety R is an alkyl group, an alkylene group, an alkinyl group, an alicyclic group or an aromatic group.

The organic moiety R can also contain two or more differing alkyl groups, alkylene groups, alkinyl groups, alicyclic groups or aromatic groups which are connected to each other by multi-functional linking groups, preferably bifunctional linking groups.

Additionally, the organic moiety R can also contain at least two groups selected from different classes of groups, as for example, one alkyl group and one alicyclic group, or two alkyl groups which are linked by an aromatic group. The groups selected for the organic moiety R can be connected to each other by carbon-carbon bonds and/or multi-functional linking groups, preferably bifunctional linking groups.

Furthermore, the organic moiety R can be monofunctional or multi-functional, preferably monofunctional (R—) or bifunctional (—R—).

More preferably, the aliphatic groups or alkyl groups are derived from aliphatic hydrocarbons selected from the group consisting of substituted and unsubstituted ethane propane, iso-propane butane, isobutane, pentane, isopentane, neopentane, hexane, heptane, octane, isooctane, 2-methyl-heptane, 2-methyl-hexane, nonane, decane, undecane, dodecane, tridecane, tetradecane, pentadecane and hexadecane, preferably ethane, propane, butane, isobutane, hexane, octane and dodecane;

More preferably, the olefinically unsaturated groups or alkenyl groups are derived from olefins selected from the group consisting of substituted and unsubstituted ethylene, propylene, but-1-ene, but-2-ene, pent-1-ene, pent-2-ene, hex-1-ene, hex-2-ene, hept-1-ene, oct-1-ene, oct-2-ene, oct-3-ene, non-1-ene, dec-1-ene, dodec-1-ene, undec-1-ene, dodec-1-ene, tridec-1-, tetradec-1-ene, pentadec-1-ene, and hexadec-1-, -2-, -3-, -4-, -5-, -6-, -7- and -8-ene, in particular ethylene.

More preferably, the acetylenically unsaturated groups or alkinyl groups are derived from acetylenically unsaturated hydrocarbons selected from the group consisting of substituted and unsubstituted acetylene, propyne, but-1-yne, but-2-yne, pent-1-yne, pent-2-yne, hex-1-yne, hex-2-yne, hept-1-yne and oct-1-, -2-, -3- and -4-yne, in particular acetylene and propyne;

More preferably, the alicyclic groups are derived from alicyclic compounds selected from the group consisting of substituted and unsubstituted cyclopropane, cyclobutane, cyclopentane, cyclohexane, cyclohexene, norbonane and adamantane, in particular cyclopentane and cyclohexane.

More preferably, the aromatic groups are derived from aromatic compounds selected from the group consisting of substituted and unsubstituted benzene, biphenyl, naphthalene, anthracene and phenanthrene, in particular benzene.

When used, the multi-functional linking groups are preferably selected from the group consisting of:

### —O—, —C(O)—, —C(S)—, —C(O)—O—, —O—C(O)—O—, —O—C(S)—O—;

—(—O—)₂Si(—R²)₂, —(—O—)₃S¹—R² with R² as hereinafter defined;
—NR¹—, ═N—, —N═N—, —NR¹—C(O)—, —NR¹—NR¹—C(O)—, —NR¹—NR¹—C(S)—, —O—C(O)—NR¹—, —O—C(S)—NR¹—, —NR¹—C(O)—NR¹—, —NR¹—C(S)—NR¹—;

### —(—O—)₃P(O), —(—O—)₃P(S), —(—O—)₂P(O)—, —(—O—)₂P(S)—, —(—NR¹—)₃P(O), —(—NR¹—)₃P(S), —(—NR¹—)₂P(O)—, —(—NR¹—)₂P(S)—;

### —S—, —S(O)—, —S(O)₂—, —O—S(O)₂—, and —NR¹—S(O)₂—.

In these formulas R¹ is selected from the group consisting of hydrogen and substituted and unsubstituted methyl and the organic moieties R. R² is R¹ except hydrogen.

The linking group being most preferred is —C(O)—O—.

When used, the substituents of the substituted organic moieties R are preferably selected from the group consisting of:

### —OR¹, —C(O)—R¹, —COOR¹, —SO₃R¹, —P(O)₂R¹, —N(—R¹)₂,

### —NR¹—C(O)(—R¹)₂;

-oxirane, -aziridine bonded via nitrogen or via carbon, and methacryloyl group bonded via oxygen;

### —F, —Cl, —CN and —NO₂;

wherein R¹ has the above described meaning.

Most preferably, the substituents are —NH₂, oxirane, and methacryloyl group bonded via oxygen.

Most preferably, the organic moiety R of the formula I is selected from the group consisting of ethyl, n-butyl, 3-butyl, hexyl, octyl, dodecyl, vinyl, methacryloyloxypropyl, aminopropyl and glycidoxypropyl, in particular hexyl, octyl, dodecyl and vinyl, and, most particularly preferred, octyl.

In the formula I the variable X symbolizes a hydrolyzable atom or moiety.

Preferably, the hydrolyzable atoms X are selected from the group consisting of hydrogen, chlorine, bromine and iodine.

The hydrolyzable moieties X are selected from the group consisting of groups of the formula II:

—Y—R¹ (II),

wherein the variable Y is a bifunctional linking group selected from the group consisting of —O—, —S—, —C(O)—, —C(S)—, —O—C(O)—, —S—C(O)—, —O—C(S)— and —NR¹—, wherein R¹ has the above described meaning.

Y is most preferably —O— and R¹ is most preferably methyl or ethyl. Therefore, the most preferably used hydrolyzable moieties X are —O—CH₃ and —O—C₂H₅, in particular —O—C₂H₅.

Preferably, the silanes I are used.

More preferably, the at least one silane I is selected from ethyl-, n-butyl-, 3-butyl-, hexyl-, octyl-, dodecyl-, vinyl-, methacryloyloxypropyl-, aminopropyl- and glycidoxypropyltrimethoxy- and -triethoxysilane and, even more preferably, from hexyl-, octyl-, dodecyl- and vinyltriethoxysilane. Most preferably, octyltrimethoxysilane and/or octyltriethoxysilane is or are used.

Most particularly preferably, a mixture comprising at least one first silane I selected from octyltrimethoxysilane and octyltriethoxysilane and at least one second silane I selected from hexyl-, octyl-, dodecyl- and vinyltrimethoxy- and -triethoxysilane is used. Particularly, the mixture comprises the triethoxysilanes.

In the mixture comprising at least one first silane I and at least one second silane I, the molar ratio of the first silane I to the second silane I can vary broadly. Preferably, the molar ratio is from 10:1 to 1:10, more preferably from 7.5:1 to 1:7.5, even more preferably from 5.:1 to 1:5, and, most preferably, 3:1 to 1:3.

The silanes I and/or II are applied as organic solutions, containing at least one organic solvent.

The organic solvent is selected such that it does not react with or decompose the silane I. A polar organic solvent is preferably used. More preferably, the polar organic solvent is selected from the group consisting of alcohols, ketones and ethers, most preferably, low boiling alcohols, such as methanol, ethanol, propanol and isopropanol, ketones such as acetone and methyl ethyl ketone, and ethers such as diethyl ether and tetrahydrofurane. Ethanol is particularly preferably used.

Preferably, the organic solvent contains a small amount of at least one acid selected from the group of organic and inorganic acids, preferably selected from the group consisting of formic acid, acetic acid, benzene sulfonic acid, toluene sulfonic acid, sulphuric acid, nitric acid, and hydrochloric acid, in order to render the organic solvent slightly acidic and to promote the hydrolyzation of the hydrolyzable moieties or atoms X of the silanes I and/or II. Hydrochloric acid is particularly preferably used.

Additionally, the organic solvent can contain at least one functional additive, preferably selected from commercial surfactants and wetting agents customarily used. Suitable additives of this kind are, for example, Octowet™ 17 from Tiarco Chemicals or Surfynol™ 104H from AirProducts.

Moreover, the organic solvent can contain at least one silane other than the silanes I and/or II described above, as for example, methyl- or ethyltrimethoxysilane or methyl- or ethyltriethoxysilane.

Preferably, the organic solution of the at least one silane I and/or II is highly diluted. More preferably, the concentration of the silane I and/or II is from 0.01 to 2% by weight, most preferably from 0.05 to 1% by weight and, in particular, from 0.07 to 0.75% by weight, each based on the complete weight of the organic solution.

The organic solution of the at least one silane I and/or II is applied onto at least one major surface of the silicon carbide layer (A). Preferably, the organic solution is applied in amounts corresponding to a dry thickness of the stratum (B) of from 5 to 100 nm. All methods and devices for the application of organic solutions onto flat surfaces which are known in the art can be used in the process of the invention. Preferably, dip coating, curtain coating, spray coating, roller coating, spin coating, bar coating, case knife system coating or blade coating, in particular, spin coating, can be used.

In the second process step of the process of the invention, the applied layer consisting of the organic solution of the at least one silane I and/or II is dried by removing the volatile components such as the organic solvents and the acids if used preferably by evaporation. The evaporation can be carried out at a constant atmospheric pressure or in a constant vacuum. One can also start the evaporation at atmospheric pressure and lower the pressure during the course of the operation. Moreover, the evaporation can be carried out at a constant temperature, preferably, at a constant temperature between 10 to 120° C., more preferably 20 to 100° C., and most preferably 25 to 90° C. However, the temperature can also be raised from a starting temperature, preferably 10° C., to a final temperature, preferably 120° C., more preferably 20 to 100° C., and most preferably 25 to 90° C., during the course of the operation. The time period for carrying out this operation can vary broadly. Preferably it is carried out within 1 to 240 min, more preferably 5 to 120 min and most preferably 10 to 60 min.

In the third process step of the process of the invention, the dried layer of the at least one silane I and/or II is annealed at temperatures between 150 and 400° C., preferably between 200 and 350° C. and most preferably between 250 and 350° C. for 1 to 120 min, preferably 5 to 90 min and most preferably 10 to 60 min to obtain the stratum (B). Preferably, the annealing is carried out in an oxygen containing atmosphere.

Preferably, the annealing step is carried out such that all of the silanes I and/or II or at least one of the silanes I and/or II contained in the dried layer is or are partially or completely decomposed, thereby yielding a stratum (B) still exhibiting some or no absorption in its IR spectrum in the wavenumber range of from 3000 to 2800 cm⁻¹ indicating the presence of some moieties having aliphatic carbon-hydrogen bonds or a concentration of such moieties which is below the limit of detection.

In the fourth process step of the process of the invention, at least one inorganic dielectric layer (C) is applied onto the stratum (B), the said inorganic dielectric layer (B) covering the stratum (B) partially or completely, preferably completely. The manufacture of the inorganic dielectric layer (C) can be carried out with materials, methods and devices well-known in the art. Examples of such materials, methods and devices are described in the above mentioned patent applications and patents U.S. Pat. No. 6,827,982 B1, WO 01/78127 A2, WO 2004/027850 A1 and U.S. Pat. No. 6,424,038 B1.

In the alternative, the fourth process step can be carried out directly after the first process step, whereafter the second and third process steps are carried out during and/or after the fourth process step

The structures of the invention and the layered structures manufactured by the process of the invention exhibit an excellent interlayer adhesion. Due to their excellent electronic properties they can be most advantageously used in a wide range of novel electronic devices, in particular novel semiconductor devices such as LEDs, IGFETs, MOSFETs, insulated gate bipolar transistors, Schottky diodes, thyristors and integrated circuits.

In these novel semiconductor devices, the silicon carbide layers (A) of the structures of the invention are preferably used as semiconductor material and/or function as etch stop layers in the manufacture of the semiconductor devices, in particular ICs, and/or as copper barrier layers and protective layers in semiconductor devices, in particular ICs.

### Examples and Comparative Experiments

### Comparative Experiment 1

### The Manufacture of a Structure Comprising a Silicon Carbide Layer (A), a Silane Layer and an Inorganic Dielectric Layer (C)

### The Manufacture of Silane Coating on the Silicon Carbide Layer (A):

2 ml of hydrochloric acid having a concentration of 1 mol/l were added to 96 ml of ethanol. Thereafter, 2 ml of octyltriethoxysilane (OCTEO) were added to this solution and the resulting solution was stirred for 20 hours at room temperature. A small amount of the OCTEO solution was diluted with additional ethanol until a concentration of the hydrolyzate of OCTEO of 0.1% by weight was reached. The solution was applied to the surface of a silicon carbide layer located on top of a silicon wafer with a case knife system using a doctor blade. The coating thus obtained was dried at room temperature. The contact angle of the dried coating with water was measured with the dynamic sessile drop method using a contact angle goniometer with a high-speed camera. A contact angle of 91° was obtained after 1 second, which was much higher than the contact angle of the pure silicon carbide layer (A) with water, which angle was 54°. For purposes of comparison the contact angle of a silicon dioxide surface with water was also measured. The contact angle was 38°. The IR spectrum of the silane coating showed strong C—H absorption bands between 3000 and 2800 cm⁻¹. The thickness of the silane coating was 15 nm.

### The Manufacture of an Inorganic Dielectric Layer (C) on the Silane Coating:

An inorganic dielectric layer (C) of the thickness of 50 nm was applied to the silane coating as described in the American U.S. Pat. No. 6,827,982 B1 using silicalite nanoparticles (SilicaLite™ available from Novellus Systems, Inc. of San Jose, Calif.) dispersed in tetraethylorthosilicate (TEOS).

### Adhesion Measurements:

The interface adhesion between the silane coating and the inorganic dielectric layer (C) was tested with the Scotch Brite test. In the test, the inorganic dielectric layer was partially ripped off from the silane coating, which demonstrated that the adhesion was not sufficient for practical purposes.

This was corroborated by a scribe test. In this test, the inorganic dielectric layer (C) was scribed with a glass cutter. Scanning electron microscope (SEM) pictures were taken from the scratches and inspected. The SEM pictures showed severe delamination in the vincinity of the scratches.

### Example 1

### The Manufacture of a Structure Comprising a Silicon Carbide Layer (A), Stratum (B) and an Inorganic Dielectric Layer (C)

### The Manufacture of a Silicon Carbide Layer (A) Having a Stratum (B):

The silane coating of the Comparative Experiment 1 was annealed in an oxygen containing atmosphere for 30 min at 300° C. The stratum (B) of a thickness of 10 nm having a contact angle with water of 44° was obtained. Some C—H absorption bands at 3000 to 2800 cm-1 were still present in its IR spectrum.

### The Manufacture of an Inorganic Dielectric Layer (C) on the Stratum (B):

An inorganic dielectric layer (C) of the thickness of 50 nm was applied to the silane coating as described in the American U.S. Pat. No. 6,827,982 B1 using silicalite nanoparticles (SilicaLite™ available from Novellus Systems, Inc. of San Jose, Calif.) dispersed in tetraethylorthosilicate (TEOS).

### Adhesion Measurements:

The interface adhesion between the stratum (B) and the inorganic dielectric layer (C) was tested with the Scotch Brite test. The inorganic dielectric layer (C) could not be removed in the test, which demonstrated the excellent interface adhesion. This was also corroborated by the scribe test. The obtained SEM pictures showed no delamination at the scratches.

### Examples 2 and 3 and Comparative Experiment 2

### The Manufacture of Structures Comprising a Silicon Carbide Layer (A), a Stratum (B) and an Inorganic Dielectric Layer (C) Using Silanes I (Examples 2 and 3) and Methyltriethoxysilane (Comparative Experiment 2)

For the Examples 2 and 3, Example 1 was repeated under similar conditions except that other silanes I than OCTEO and slightly varying conditions were used. The Table 1 summarizes the employed conditions and silanes I.

TABLE 1
Experimental Conditions Used in the Examples 2 to 6 and the Comparative Experiment 2

| | Ethanol | HCl | | Amount | Layer Thickness | Contact angle |
|---|---|---|---|---|---|---|
| | (ml) | (ml) | Silane I | (g) | (nm) | (°) |
| Example No. | | | | | | |
| 2 | 96.19 | 2 | hexyltriethoxysilane | 1.81 | 15 | 88 |
| 3 | 96.5 | 2 | dodeclytriethoxy- | 1.5 | 15 | 96 |
| | | | silane | | | |
| Comparative | | | | | | |
| Exp. | | | | | | |
| 2 | 95.34 | 2 | methyltriethoxy- | 2.66 | 15 | 69 |
| | | | silane | | | |

The layered structures containing the silane coatings were annealed as described in the Example 1 using the conditions summarized in Table 2. The contact angles of the strata (B) of the Examples 2 and 3 and of the silane layer of the Comparative Experiment 2 obtained after the annealing step are also summarized in Table 2.

TABLE 2
Annealing Conditions Used in the Examples 2 to 6 and in the
Comparative Experiment 2

| | Temperature | Layer Thickness | Contact angle |
|---|---|---|---|
| | (° C.) | (nm) | (°) |
| Example | | | |
| No. | | | |
| 2 | 300 | 10 | 48 |
| 3 | 300 | 10 | 48 |
| Comparative | | | |
| Exp. | | | |
| 2 | 300 | 10 | 75 |

The layered structures of the Examples 2 and 3 exhibited the same excellent interface adhesion as the layered structure of the Example 1, whereas the layered structure of the Comparative Experiment 2 exhibited an inferior interface adhesion.

### Examples 4 and 5

### The Manufacture of Structures Comprising a Silicon Carbide Layer (A), a Stratum (B) and an Inorganic Dielectric Layer (C) Using a Silane I and Methyltriethoxysilane (Example 4) or Two Silanes I (Example 5)

### Example 4

The following two solutions 1 and 2 were used for the Example 4.

Solution 1: 20.50 g 2-propanol
11.40 g octyltriethoxysilane (M: 276.48/0.04 mol/purity: 97%)
4.50 g distilled water
12.5 μl conc. HCl (37% ig)
   Solution 2: 20.50 g 2-propanol
7.30 g methyltriethoxysilane (M: 178/0.04 mol/purity: 98%)
4.50 g distilled water
12.5 μl conc. HCl (37%)

Under stirring with a magnetic stirring bar, each of the silanes was dissolved in the 20.50 g 2-propanol. Thereafter 4.50 g distilled water and 12.5 μl of concentrated hydrochloric acid were added to the solution and both solution were separately stirred for 20 hours at room temperature. After stirring for 20 hours 3 ml of solution 1 and 1 ml of solution 2 were mixed and diluted with 25 ml 2-propanol. Finally, 0.1 ml of a 1 wt % solution of Octowet™ 70 (commercial surfactant from Tiarco Chemicals) in 2-propanol was added.

3.2 ml of the resulting formulation were poured on a SiC coated wafer having a size of 10×10 cm. After the addition of the solution had been completed, the coated wafer was spun with 500 rpm for 4 seconds on the spin coater Primus STT 15 from SSE (Sister Semiconductor Equipment GmbH, Germany). The rotational speed was increased to 1500 rpm for 21 seconds and again reduced to 500 rpm for 5 seconds. After the rotation was stopped, the wafer was placed on a hot plate at 60° C. for 10 min.

Finally, the layered structure containing the dried silane coating was annealed in an oxygen containing atmosphere for 30 min at 300° C. The resulting coating of the SiC wafer was homogeneous and free of any cracks. The water contact angle before annealing was 80°. After annealing the stratum (B) of a thickness of 25 nm having a contact angle with water of 47° was obtained. Some C—H absorption bands at 3000 to 2800 cm⁻¹ were still present in the IR spectrum.

### Example 5

The following two solutions 1 and 3 were used for the Example 5.

Solution 1: 20.50 g 2-propanol
11.40 g octyltriethoxysilane (M: 276.48/0.04 mol/purity: 97%)
4.50 g distilled water
12.5 μl conc. HCl (37% ig)
   Solution 3: 20.50 g 2-propanol
10.25 g hexyltriethoxysilane (M: 248.44/0.04 mol/purity: 97%)
4.50 g distilled water
12.5 μl conc. HCl (37%)

Under stirring with a magnetic stirring bar, each of the silanes was dissolved in the 20.50 g 2-propanol. Thereafter, 4.50 g distilled water and 12.5 μl of concentrated hydrochloric acid were added to each solution and both solutions were separately stirred for 20 hours at room temperature. After stirring for 20 hours, 3 ml of solution 1 and 1 ml of solution 3 were mixed and diluted with 25 ml 2-propanol. Finally 0.1 ml of a 1 wt % solution of Octowet™ 70 in 2-Propanol was added.

3.2 ml of the resulting formulation were poured on a SiC coated wafer with a size of 10×10 cm. After the addition of the solution was completed, the coated wafer was spun with 500 rpm for 4 seconds on the spin coater Primus STT 15 from SSE (Sister Semiconductor Equipment GmbH, Germany). The rotational speed was increased to 1500 rpm for 21 seconds and again reduced to 500 rpm for 5 seconds. After the rotation was stopped, the wafer was placed on a hot plate at 60° C. for 10 min.

Finally, the layered structure containing the silane coating was annealed in an oxygen containing atmosphere for 30 min at 300° C. The resulting coating of the SiC wafer showed some cracks. The water contact angle before annealing was 89°. After annealing the stratum (B) of a thickness of 20 nm having a contact angle with water of 46° was obtained. No C—H absorption bands at 3000 to 2800 cm⁻¹ were present in the IR spectrum.

Interlayer Adhesion Resulting from the Strata (B) of the Examples 4 and 5:

Each of the strata (B) was overcoated with an inorganic dielectric layer (C) as described in the Example 1. Thereafter, the interlayer adhesion was tested. All strata (B) exhibited good to excellent interlayer adhesion which completely satisfied the technical requirements of the market. The following order of interlayer adhesion was obtained for the strata (B):

Example 4>Example 5.

1. A layered structure, comprising in this order
(A) a silicon carbide layer;
(B) at least one stratum
(b1) located on at least one major surface of the silicon carbide layer (A),
(b2) chemically bonded to a bulk of the silicon carbide layer (A) by silicon-oxygen and/or silicon-carbon bonds,
(b3) covering the at least one major surface of the silicon carbide layer (A) partially or completely,
(b4) having
a higher polarity than a pure silicon carbide surface as shown by a contact angle with water which is lower than the contact angle of water with a pure silicon carbide surface and
a contact angle with water equal to or greater than the contact angle of water with a pure silicon dioxide surface,
the contact angle being measured by dynamic sessile drop as a function of time with a contact angle goniometer with a high-speed camera; and
(C) at least one dielectric layer, which covers the at least one stratum partially or completely and is selected from the group consisting of an inorganic hybrid dielectric layer and an inorganic-organic hybrid dielectric layer.

2. The layered structure according to claim 1, wherein the at least one stratum (B) has a thickness of from 1 to 100 nm.

3. The layered structure according to claim 1, wherein the inorganic and/or the inorganic-organic hybrid dielectric layer (C) comprises siloxane bonds.

4. The layered structure according to claim 1, wherein at least one dielectric layer (C) has a dielectric constant k less than silicon dioxide.

5. The layered structure according to claim 1, wherein the at least one dielectric layer (C) has a thickness of from 10 to 500 nm.

6. A process for manufacturing a layered structure, the layered structure comprising, in this order:
(A) a silicon carbide layer;
(B) at least one stratum
(b1) located on at least one major surface of the silicon carbide layer,
(b2) chemically bonded to a bulk of the silicon carbide layer by silicon-oxygen and/or a silicon-carbon bonds,
(b3) covering the at least one major surface of the silicon carbide layers partially or completely, and
(b4) having a higher polarity than a pure silicon carbide surface as shown by a contact angle with water which is lower than the contact angle of water with a pure silicon carbide surface, the contact angle being measured by dynamic sessile drop as a function of time with a contact angle goniometer with a high-speed camera; and
(C) at least one dielectric layer, which covers the at least one stratum partially or completely and is selected from the group consisting of an inorganic hybrid dielectric layer and an inorganic-organic hybrid dielectric layer,
the process comprising
(1) applying an organic solution comprising at least one organic solvent, a small amount of at least one acid and at least one silane selected from the group consisting of a silane of formula I:
RₙSiX₄₋ₙ (I),
and a silane of formula II:
RₘX₃₋ₘSi—R—SiX₃₋ₘRₘ (II),
wherein
n is 1 or 2;
m is 0 or 1;
R is an organic moiety comprising at least two carbon atoms, selected from the group consisting of a substituted linear aliphatic group, a substituted branched aliphatic group, an unsubstituted linear aliphatic group, an unsubstituted branched aliphatic group, a substituted linear olefinically unsaturated group, a substituted branched olefinically unsaturated group, an unsubstituted linear olefinically unsaturated group, an unsubstituted branched olefinically unsaturated group, a substituted linear acetylenically unsaturated group, a substituted branched acetylenically unsaturated group, an unsubstituted linear acetylenically unsaturated group, an unsubstituted branched acetylenically unsaturated group, an alicyclic group, and an aromatic group; and
X is a hydrolyzable atom or hydrolyzable moiety,
to at least one major surface of the silicon carbide layer (A), to give a solution layer;
(2) drying the solution layer obtained in (1) by removing volatile components to give a dried layer;
(3) annealing the dried layer at temperatures between 150 to 400° C. for 1 to 120 min in an oxygen comprising atmosphere to obtain the at least one stratum (B); and
(4) applying the at least one dielectric layer (C), so as to cover the at least one stratum (B) partially or completely
or, in the alternative,
(5) carrying out (4) directly after (1), and, thereafter, carrying out (2) and (3) during and/or after (4).

7. The process of claim 6, wherein the contact angle of the stratum (B) with water is equal to or greater than the contact angle of water with a pure silicon dioxide surface, and the contact angle is measured by dynamic sessile drop as a function of time with a contact angle goniometer with a high-speed camera.

8. The process of claim 6, wherein the organic solvent comprises at least one polar organic solvent.

9. The process of claim 6, wherein n=1 and m=0.

10. The process of claim 6, wherein the hydrolyzable atoms X are selected from the group consisting of hydrogen, chlorine, bromine, and iodine; and
the hydrolyzable moieties X are represented by formula II:
—Y—R¹ (II),
wherein Y is a bifunctional linking group selected from the group consisting of —O—, —S—, —C(O)—, —C(S)—, —O—C(O)—, —S—C(O)—, —O—C(S)— and —NR¹—, and
R¹ is selected from the group consisting of hydrogen, a substituted methyl group, an unsubstituted methyl group, and R.

11. The process according to claim 10, wherein X=—O— and R¹=methyl or ethyl.

12. The process of claim 6, wherein the at least one silane I is selected from the group consisting of ethyltrimethoxysilane, ethyltriethoxysilane, n-butyltrimethoxysilane, u-butyltriethoxysilane, 3-butyltrimethoxysilane, 3-butyltriethoxysilane, hexyltrimethoxysilane, hexyltriethoxysilane, octyltrimethoxysilane, octyltriethoxysilane, dodecyltrimethoxysilane, dodecyltriethoxysilane, vinyltrimethoxysilane, vinyltriethoxysilane, methacryloyloxypropyltrimethoxysilane, methacryloyloxypropyltriethoxysilane, aminopropyltrimethoxysilane, aminopropyltriethoxysilane, glycidoxypropyltrimethoxysilane, and glycidoxypropyltriethoxysilane.

13. The process according to claim 12, wherein the at least one silane I is at least one first silane I selected from the group consisting of octyltrimethoxysilane and octyltriethoxysilane, and at least one second silane I selected from the group consisting of hexyltrimethoxysilane, hexyltriethoxysilane, octyltrimethoxysilane, octyltriethoxysilane, dodecytrimethoxysilane, dodecytriethoxysilane, vinyltrimethoxysilane, and vinyltriethoxysilane.

14. An electronic device comprising the layered structure according to claim 1.

15. The device of claim 14, wherein the electronic device is a semiconductor device, and the silicon carbide layer (A) is a semiconductor material and/or an etch stop layer and/or a copper barrier layer and/or a protective layer in the semiconductor device.

16. An LED, IGFET, MOSFET, insulated gate bipolar transistor, Schottky diode, thyristor or integrated circuit comprising the layered structure of claim 1.
